(19) United States
(12) Patent Application Publication
(10) Pub. No.: US 2019/0187559 A1
(43) Pub. Date: Jun. 20, 2019

(54) NANOSTRUCTURED BLOCK COPOLYMER FILM COMPRISING A BIODEGRADABLE BLOCK OF POLYESTER TYPE

(71) Applicants: Arkema France, Colombes (FR); Centre National De La Recherche Scientifique - CNR, Paris (FR); Universite Toulouse III - Paul Sabatier, Toulouse (FR)

(72) Inventors: Christophe Navarro, Bayonne (FR); Didier Bourissou, Plaisance Du Touch (FR); Blanca Martin-Vaca, Toulouse (FR); Aline Couffin, Balsac (FR); Franck Kayser, Toulouse (FR)

(73) Assignees: Arkema France, Colombes (FR); Centre National De La Recherche Scientifique - CNR, Paris (FR); Universite Toulouse III - Paul Sabatier, Toulouse (FR)

(21) Appl. No.: 16/311,465

(22) PCT Filed: Jun. 22, 2017
(86) PCT No.: PCT/FR2017/051654

§ 371 Date: Dec. 19, 2018

(30) Foreign Application Priority Data
Jun. 24, 2016 (FR) 1655903

(51) Int. Cl. G03F 7/039; C08G 64/18; C08G 77/445; G03F 7/038; G03F 7/075

(52) U.S. Cl. CPC G03F 7/039; C08G 64/183; G03F 7/0757; G03F 7/038; C08G 77/445

(57) ABSTRACT

Provided is a block copolymer film nanostructured in nanodomains, where the copolymer includes at least one first biodegradable block of polyester type and a second block of a different chemical nature than the first block. The first block of polyester type is polybutyrolactone (PBL) and the second block is derived from an oligomer or from a polymer bearing a hydroxyl function on at least one end and acting as macro-initiator of the polymerization of β-butyrolactone (β-BL) to give polybutyrolactone (PBL).

### FIELD OF THE INVENTION

The present invention relates to the field of nanostructured block copolymers having nanodomains oriented in a particular direction.

More particularly, the invention relates to a block copolymer film comprising at least one biodegradable block of polyester type, able to be readily eliminated after structuring, and having a high phase segregation, with a small L₀ period, preferably of less than 20 nm.

The term “period”, denoted L₀ in the remainder of the description, is intended to mean the minimum distance separating two adjacent domains having the same chemical composition, separated by a domain having a different chemical composition.

### PRIOR ART

The development of nanotechnologies has made it possible to constantly miniaturize products in the field of microelectronics and microelectromechanical systems (MEMS) especially. At the current time, conventional lithography techniques no longer make it possible to meet these constant needs for miniaturization, as they do not make it possible to produce structures with dimensions of less than 60 nm.

It has therefore been necessary to adapt the lithography techniques and to create etching resists which make it possible to create increasingly small patterns with a high resolution. With block copolymers, it is possible to structure the arrangement of the constituent blocks of the copolymers by phase segregation between the blocks, thus forming nanodomains, at scales of less than 50 nm. Due to this ability to be nanostructured, the use of block copolymers in the fields of electronics or optoelectronics is now well known.

Among nanolithography resists, the hitherto most widely studied block copolymer films are films based on polystyrene-b-poly(methyl methacrylate), hereinafter denoted PS-b-PMMA. In order to be able to use such a block copolymer film as an etching resist, one block of the copolymer must be selectively removed in order to create a porous film of the residual block, the patterns of which may be subsequently transferred by etching to an underlying layer. Regarding the PS-b-PMMA film, the PMMA (poly(methyl methacrylate)) is usually removed selectively in order to create a resist of residual PS (polystyrene). In order to create such resists, the nanodomains must be oriented perpendicular to the surface of the underlying layer. Such structuring of the domains requires particular conditions such as the preparation of the surface of the underlying layer, but also the composition of the block copolymer. An important factor is the phase segregation factor, also referred to as the Flory-Huggins interaction parameter and denoted by “χ”. Specifically, this parameter makes it possible to control the size of the nanodomains. More particularly, it defines the tendency of the blocks of the block copolymer to separate into nanodomains. Thus, the product χN of the Flory-Huggins parameter χ and of the degree of polymerization N gives an indication as to the compatibility of two blocks and whether they may separate at a given temperature. For example, a diblock copolymer of strictly symmetrical composition separates into microdomains if the product χN is greater than 10.49. If this product χN is less than 10.49, the blocks mix together and phase separation is not observed at the observation temperature.

Because of the constant needs for miniaturization, it is generally sought to increase this degree of phase separation, in order to produce nanolithography resists which make it possible to obtain very high resolutions, typically less than 20 nm, and preferably less than 15 nm, while at the same time retaining certain basic properties of the block copolymer, such as a good temperature resistance of the block copolymer, or a depolymerization of the PMMA under UV treatment when the block copolymer is a PS-b-PMMA, etc.

In Macromolecules, 2008, 41, 9948, Y. Zhao et al. estimated the Flory-Huggins parameter for a PS-b-PMMA block copolymer. The Flory-Huggins parameter χ obeys the following equation: χ=a+b/T, where the values a and b are constant specific values dependent on the nature of the blocks of the copolymer and T is the temperature of the heat treatment applied to the block copolymer in order to enable it to organize itself, that is to say in order to obtain a phase separation of the domains, an orientation of the domains and a reduction in the number of defects. More particularly, the values a and b respectively represent the entropic and enthalpic contributions. Thus, for a PS-b-PMMA block copolymer, the phase segregation factor obeys the following equation: χ=0.0282+4.46/T.

This low value of the Flory-Huggins interaction parameter χ (0.04 at 298 K) therefore limits the advantage of block copolymers based on PS and PMMA for the production of structures having very high resolutions.

Research has therefore shifted onto other block copolymers, especially block copolymers combining polyester-type blocks with blocks of a different nature, of polyether or polyolefin type, for example. The development of selective polymerization methods, with a controlled and living character, has enabled the preparation of block copolymers comprising blocks of varied chemical natures and a well-defined structure. In some of these polymers, the blocks have low compatibility, which results in segregation leading to nanostructuring. The chemical nature of the blocks studied is very diverse and in recent years increased attention has been paid to incorporating a biodegradable block, especially of polyester type, which can be readily eliminated after nanostructuring. PLA (polylactic acid) and to a lesser extent PCL (polycaprolactone) are the most widely studied polyesters in this context, in particular in combination with PS (polystyrene), PDMS (polydimethylsiloxane) or else PTMSS (polytrimethylsilylstyrene) blocks. Thus, the document entitled “Ordered Nanoporous Polymers from Polystyrene-Polylactide Block Copolymers”, A. S. Zalusky et al, J. AM. CHEM. SOC. 2002, 124, 12761-12773 and the document entitled “Thin Film Self-Assembly of Poly(trimethylsilylstyrene-b-D,L-lactide) with Sub-10 nm Domains”, J. D. Cushen et al, Macromolecules, 2012, 45, 8722-8728, describe, respectively, the preparation of PS-b-PLA diblock copolymers and of PTMSS-b-PLA diblock copolymers, having nanodomains less than 10 nm in size, and the period of which is between 12 and 15 nm. Finally, the document entitled “High χ-low N Block Polymers: How Far Can We Go?”, C. Sinturel et al, ACS Macro Letters, 2015, 4, 1044-1050, describes block copolymers combining PLA with PS, PDMS or PTMSS and demonstrates the fact that a block copolymer of low number-average molecular weight, typically of less than 20 000 g/mol, enables structuring in nanodomains less than 10 nm in size and with a period L₀ of less than 20 nm.

The applicant was more particularly concerned with polyesters of polylactone type. Ring-opening polymerization of lactones has been studied for several years, since the polymers resulting therefrom have a certain industrial interest in various fields due to their biodegradability and biocompatibility. Thus, copolymers with biodegradable polyesters may be used as encapsulant in medicaments or as biodegradable implants, in particular in orthopaedics, in order to do away with operations which were necessary in the past in order to remove metal parts such as pins, for example. Such polymers may also be used in coatings and plastics formulations. The applicant was therefore concerned with these polymers, for incorporating them into block copolymers due to their biodegradability, in order to be able to readily eliminate them after nanostructuring and enable the creation of a residual porous film intended to act as nanolithography resist. Polycaprolactones and polybutyrolactones also have good physicochemical properties and good thermal stability up to temperatures of at least 200-250° C.

Organocatalysts have been developed in order to enable the ring-opening polymerization of lactones, in particular ε-caprolactone, denoted “ε-CL” in the remainder of the description. Patent applications WO2008104723 and WO200810472 and also the paper entitled “Organo-catalyzed ROP of ε-caprolactone: methanesulfonic acid competes with trifluoromethanesulfonic acid”, Macromolecules, 2008, Vol. 41, pp. 3782-3784, especially demonstrated the effectiveness of methanesulphonic acid, denoted “MSA”, as catalyst of the polymerization of ε-caprolactone.

The abovementioned documents also describe that, in combination with a protic initiator of alcohol type, SMA is able to promote the controlled polymerization of the ε-caprolactone cyclic monomer. In particular, the protic initiator enables fine control of the average molar masses and also the chain ends.

PBL (polybutyrolactone) or PHB (poly-3-hydroxybutyrate) is a biodegradable polymer which can be prepared by ring-opening polymerization of β-butyrolactone (in this case reference is made to PBL) or microbially starting from the acid 3-hydroxybutyrate (reference is then made to PHB). The document entitled “Selective O-acyl ring-opening of β-butyrolactone catalyzed by trifluoromethane sulfonic acid: application to the preparation of well-defined block copolymers”, A. Couffin et al, Polym. Chem., 2014, 5, 161-168, more particularly describes that trifluoromethanesulphonic acid, also referred to as triflic acid and abbreviated to HOTf, is an organic catalyst of choice for carrying out the controlled polymerization of β-butyrolactone (BBL) in the presence of alcohol. This catalyst, HOTf, is to date the only organic catalyst enabling the block copolymerization of BBL with other monomers of lactone or carbonate type. The PBL polymer is biobased since it is derived from raw materials of renewable origin, it is biodegradable and biocompatible. By virtue of these properties, such a polymer has applications in the medical and packaging fields, especially.

In order to alter its properties and adjust them to the various applications targeted, block copolymers based on this polymer have also been studied. Thus, polybutyrolactone (PBL) or PHB (poly-3-hydroxybutyrate), depending on the synthesis method, was incorporated into block copolymers in combination with other polymer blocks. The document entitled “PLA-PHB-PLA Triblock Copolymers: Synthesis by Sequential Addition and Investigation of Mechanical and Rheological Properties”, D. C. Aluthge et al, Macromolecules, 2013, 46, 3965-3974, describes the synthesis of triblock copolymers of polybutyrolactone prepared microbially and of poly(lactic acid). The document entitled “Macromolecular Engineering of Lactones and Lactides. Controlled synthesis of (R,S)-β butyrolactone-b-ε caprolactone Block Copolymers by Anionic and Coordination Polymerization”, P. Kurcok et al, Macromolecules, 1997, 30, 5591-5595, describes the synthesis of block copolymers of PBL-b-PCL. The document entitled “Crystallinity-Induced Biodegradation of Novel [(R,S)-β-Butyrolactone]-b-pivalolactone Copolymers”, M. Scandola et al, Macromolecules, 1997, 30, 7743-7748, describes the synthesis of block copolymers of PBL-b-PHV. The document entitled “Contact Angle, WAXS, and SAXS analysis of Poly(β-hydroxybutyrate) and Poly(ethylene glycol) Block Copolymers Obtained via azotobacter vinelandii UWD”, K. J. Towsend et al, Biotechnol. Prog, 2005, 21, 959-964, describes the preparation of block copolymers of PHB-b-PEG by combining PHB with a PEG polyether block. However, unlike the block copolymers studied previously which incorporate PLA or PCL, these documents do not study, or only study to a small extent, the ability of these copolymers to be nanostructured, since the applications targeted in these documents do not relate to resists intended for nanolithography but rather to the medical field and in particular the encapsulation of medicaments.

Block copolymers combining isotactic PHB with polyesters such as PLA, PCL or PHV exhibit phase separation induced by the high crystallinity of these polymers. However, differential scanning calorimetry (DSC) analyses demonstrate a single glass transition temperature Tg, intermediate between the Tgs of the corresponding homopolymers. This result makes it possible to deduce therefrom that the amorphous phases of these block copolymers are miscible. The copolymers with PEG exhibit similar behaviour.

Only the document entitled “Poly[(R)-3-hydroxybutyrate)]/Poly(styrene) Blends Compatibilized with the Relevant Block Copolymer”, M. A. Abdelwahab et al, Journal of polym. Science part A, 2012, 50, 5151-5160, describing the preparation of block copolymers by combining PHB with polyvinylaromatic blocks, more particularly PS (polystyrene) blocks, mentions phase segregation of the copolymer. The copolymer described in this document is a copolymer of PS-b-PHB-b-PS (the molar mass Mₙ of which=8400 g/mol, and the polydispersity index Ð of which=1.58), prepared from a dibrominated telechelic PHB (Mₙ=6000 g/mol, Ð=1.58) used as macro-initiator, to carry out copper-catalysed atom transfer radical polymerization (ATRP) of the styrene. The aim of this study was the preparation of the PS-b-PHB-b-PS copolymer with the purpose of compatibilizing the mixture of the two homopolymers. DSC characterization of this copolymer shows two distinct glass transition temperature values, T_{g}, at values close to those of the homopolymers, which is in agreement with a phase segregation. The absence of melting point Tₘ also indicates that the two blocks are amorphous. According to this document, analysis by atomic force microscopy (AFM) of such a film, after a period of annealing for 24 h at 120° C., shows that nanostructuring with a lamellar morphology, with a period of 40 nm, is obtained.

Such a period is however still too long to be able to use such a block copolymer film as nanolithography etching resist, by directed self-assembly (DSA), for the new generation of applications in organic electronics. Moreover, this document only demonstrates a single lamellar morphology and does not mention any possibility of controlling the morphology of the nanodomains as a function of the composition of the block copolymer.

The applicant therefore sought a solution in order to synthesize a block copolymer film comprising at least one biodegradable block, of polyester type, which becomes nanostructured with a controlled period and morphology, so as to be able to use it as a nanolithography resist.

More particularly, the block copolymer film must have a period of less than or equal to 20 nm.

### Technical Problem

The aim of the invention is thus to overcome at least one of the disadvantages of the prior art. The invention especially aims to propose a block copolymer film nanostructured in nanodomains, said copolymer comprising at least one first biodegradable block of polyester type and being capable of becoming nanostructured in nanodomains with a controlled morphology and with a controlled period L₀ of less than 20 nm.

### BRIEF DESCRIPTION OF THE INVENTION

Surprisingly, it was discovered that a block copolymer film nanostructured in nanodomains, said copolymer comprising at least one first biodegradable block of polyester type and a second block of a different chemical nature than the first block, said block copolymer being characterized in that the first block of polyester type is polybutyrolactone (PBL) and in that the second block is derived from a polymer bearing a hydroxyl function on at least one end and acting as macro-initiator of the polymerization of β-butyrolactone (BBL) to give polybutyrolactone (PBL), makes it possible to obtain nanodomains with a perfectly defined and controlled morphology, with a period L₀ of less than 20 nm.

According to other optional features of this block copolymer film:
the block copolymer is a diblock or triblock copolymer;
the number-average molecular weight of each PBL block is between 1000 and 20 000 g/mol;
the number-average molecular weight of the block copolymer is between 2000 and 30 000 g/mol;
the molar ratio of monomer (β-BL) to macro-initiator is between 60/1 and 160/1;
the second block, forming the macro-initiator, is derived from an oligomer or from a mono- or polyhydroxylated polymer chosen from: (alkoxy)polyalkylene glycols, such as (methoxy)polyethylene glycol (MPEG/PEG), polypropylene glycol (PPG) and polytetramethylene glycol (PTMG); poly(alkyl)alkylene adipate diols, such as poly(2-methyl-1,3-propylene adipate) diol (PMPA) and poly(1,4-butylene adipate) diol (PBA); polysiloxanes, such as mono- or dihydroxylated polydimethylsiloxane (PDMS), or optionally hydrogenated mono- or dihydroxylated polydienes, such as α,γ-dihydroxylated polybutadiene or α,ω-dihydroxylated polyisoprene, preferably hydrogenated or non-hydrogenated hydroxytelechelic polybutadiene; or mono- or polyhydroxylated polyalkylenes such as mono- or polyhydroxylated polyisobutylene; modified or unmodified polysaccharides such as starch, chitin, chitosan, dextran and cellulose; or a vinyl co-oligomer or copolymer from the family of acrylic, methacrylic, styrene or diene polymers, which results from copolymerization between acrylic, methacrylic, styrene or diene monomers and functional monomers having a hydroxyl group, or a vinyl copolymer obtained by controlled radical polymerization, in which the radical initiator and/or the control agent bear at least one hydroxyl or thiol function.

Starting from this film, it is possible to produce a nanolithography resist by removing the first polybutyrolactone (PBL) block to form a porous pattern perpendicular to the surface to be etched which has a period L₀ 20 nm.

Other distinctive features and advantages of the invention will become apparent on reading the following description given by way of illustrative and non-limiting example.

### DETAILED DESCRIPTION OF THE INVENTION

The term “monomer” as used relates to a molecule which can undergo a polymerization.

The term “polymerization” as used relates to the process of conversion of a monomer or of a mixture of monomers into a polymer.

The term “oligomer” as used relates to a small polymeric compound comprising between 2 and 30 monomers, that is to say the degree of polymerization of which is between 2 and 30.

The term “copolymer block” or “block” is intended to mean a polymer which groups together several monomer units of several types or of the same type.

The term “block copolymer” is intended to mean a polymer comprising at least two blocks as defined above, the two blocks being different from one another and having a phase segregation parameter such that they are not miscible and separate into nanodomains.

The term “miscibility” used above is used to mean the ability of two compounds to mix together completely so as to form a homogeneous phase.

The block copolymer according to the invention advantageously comprises a first biodegradable block of polyester type, able to be readily eliminated after nanostructuring the copolymer, so as to produce a porous film intended to act as nanolithography resist. The block copolymer comprises at least one other block different from the first and which is incompatible with the first block, that is to say that they cannot be mixed and they separate into nanodomains.

The first block of polyester type is preferably polybutyrolactone, denoted PBL in the remainder of the description. The second block is formed from an oligomer or from a polymer, the chemical nature of which is incompatible with polybutyrolactone, and comprising an alcohol function on at least one end. This second alcohol-functionalized polymer makes it possible to act as macro-initiator for the polymerization of β-butyrolactone (BBL) in the presence of triflic acid (HOTf) as catalyst. When it only comprises one hydroxyl function on one end, it makes it possible to produce a diblock copolymer with PBL. When it comprises a hydroxyl function at both its ends, it makes it possible to synthesize a triblock copolymer with PBL blocks at the ends.

This second polymer forming the second block of the block copolymer and acting as macro-initiator of β-butyrolactone (BBL) may advantageously be chosen from an oligomer or a mono- or polyhydroxylated polymer, especially chosen from: (alkoxy)polyalkylene glycols, such as (methoxy)polyethylene glycol (MPEG/PEG), polypropylene glycol (PPG) and polytetramethylene glycol (PTMG); poly(alkyl)alkylene adipate diols, such as poly(2-methyl-1,3-propylene adipate) diol (PMPA) and poly(1,4-butylene adipate) diol (PBA); polysiloxanes, such as mono- or dihydroxylated polydimethylsiloxane (PDMS); optionally hydrogenated, α-hydroxylated or α,ω-dihydroxylated polydienes, such as α,γ-dihydroxylated polybutadiene or α,ω-dihydroxylated polyisoprene; mono- or polyhydroxylated polyalkylenes such as mono- or polyhydroxylated polyisobutylene; modified or unmodified polysaccharides such as starch, chitin, chitosan, dextran and cellulose; and mixtures thereof.

According to another possibility, the macro-initiator may be a vinyl co-oligomer or copolymer from the family of acrylic, methacrylic, styrene or diene polymers, which results from copolymerization between acrylic, methacrylic, styrene or diene monomers and functional monomers having a hydroxyl group, such as hydroxylated methacrylic or acrylic monomers, such as, for example, 4-hydroxybutyl acrylate, hydroxyethyl acrylate and hydroxyethyl methacrylate. This polymerization may be carried out according to a conventional radical process, a controlled radical process or an anionic process.

According to yet another possibility, the macro-initiator may be a vinyl copolymer obtained by controlled radical polymerization, in which the radical initiator and/or the control agent bear at least one hydroxyl or thiol function.

Preferably, the macro-initiator is advantageously chosen from hydroxylated polyolefins, that is to say any polymer derived from olefins bearing at least one hydroxylated or hydroxytelechelic function. Polydienes are particularly targeted and, among the polydienes, polybutadienes and most particularly hydroxytelechelic polybutadiene are preferred.

More preferably, the hydroxytelechelic polybutadiene is a polymer sold by Cray Valley under the trade name Krasol® and more particularly Krasol LBH-P3000® and Krasol HLBH-P3000®. Krasol LBH-P3000® is a polybutadiene prepared by anionic polymerization with a number-average molecular weight Mₙ of approximately 3200 g/mol. Krasol HLBH-P3000® is a hydrogenated polybutadiene, the number-average molecular weight Mₙ of which is approximately 3100 g/mol. These dihydroxylated macro-initiators make it possible to synthesize triblock copolymers of PBL-Krasol®-PBL with a central block of polybutadiene (PBT) type, hydrogenated or non-hydrogenated.

The formulations of Krasol LBH-P3000® and Krasol HLBH-P3000® used are as follows:

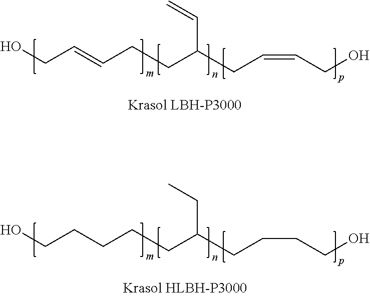

The number-average molecular weight of each PBL block is preferably between 1000 and 20 000 g/mol.

The number-average molecular weight of the block copolymer obtained is between 2000 and 30 000 g/mol.

The volume fraction of polyester, PBL, relative to the total volume of the block copolymer, may vary between 25% and 75%. This volume fraction advantageously makes it possible to control the morphology of the nanodomains formed. Thus, when the volume fraction of PBL in the copolymer is between 45 and 55%, the copolymer has a lamellar morphology, and when the volume fraction of PBL in the copolymer is between 65 and 75%, the copolymer has a cylindrical morphology.

The volume fraction of each block of the block copolymer is measured in the manner described hereinafter. Within a block copolymer, it is possible to measure, by proton NMR, the molar fraction of each polymer in the whole of the copolymer, and then to work back to the mass fraction using the molar mass of each polymer constituting a block. The volume fraction of each block can then be determined from the mass fraction of each block and from the density of the polymer forming the block. Taking the example of a PBL-b-Krasol®, it is possible to determine the molar fraction of each polymer block in the whole of the copolymer, by proton NMR, by integrating the olefinic protons of the Krasol®, the CHO protons of the PBL block and the proton of the end —CHOH function of the PBL block. Using the molar masses of each monomer unit (rounded up, for example, to 86 g/mol for BBL and 3200 g/mol for Krasol®), it is then possible to calculate the mass fraction of each block. Thus, in the example, the copolymer comprises 50% by mass of BBL monomer units and 50% by mass of macro-initiator units. In order to determine the volume fraction of the 1^{st} PBL block, the density of the PBL is thus used (d=1.25, and d=0.9 for Krasol®). This density is known and indicated, for example, in the Polymer Handbook.

The process for synthesizing such a block copolymer film comprises the steps consisting in mixing the macro-initiator, for example a macro-initiator of hydroxylated polyolefin type, and more particularly a hydroxylated or dihydroxylated polybutadiene, with β-butyrolactone (BBL), in a solvent, in the presence of trifluoromethanesulphonic acid as catalyst for the β-butyrolactone polymerization reaction, in order to selectively obtain, in one step, a block copolymer. The solvent is advantageously chosen from toluene, ethylbenzene and xylene. Toluene is, however, preferred to the two other solvents. The catalyst is then eliminated and the block copolymer solution obtained is applied in the form of a film to a surface to be etched, the surface energy of which has been previously neutralized. The solvent of the solution is evaporated and the film is subjected to annealing at a temperature determined to ensure the nanostructuring of the copolymer in nanodomains perpendicular to the surface to be etched.

Generally, in the case of lithography, the desired structuring, for example the generation of nanodomains perpendicular to the surface, requires, however, the preparation of the surface on which the copolymer solution is deposited with a view to controlling the surface energy. Among the known possibilities, a random copolymer, the monomers of which can be entirely or partially identical to those used in the block copolymer which it is desired to deposit, is deposited on the surface. In a pioneering article, Mansky et al. (Science, Vol. 275, pages 1458-1460, 1997) gives a good description of this technology, now well known to those skilled in the art.

Mention may be made, among the favoured surfaces, of the surfaces consisting of silicon, the silicon having a native or thermal oxide layer, germanium, platinum, tungsten, gold, titanium nitrides, graphenes, BARC (Bottom Anti-Reflective Coating) or any other anti-reflective layer used in lithography.

Once the surface has been prepared, a solution of the block copolymer according to the invention is deposited and then the solvent is evaporated off according to techniques known to those skilled in the art, such as, for example, the spin coating, doctor blade, knife system or slot die system technique, but any other technique can be used, such as dry deposition, that is to say deposition without involving a predissolution.

A heat treatment is then carried out, which enables the block copolymer to become correctly organized, that is to say to especially obtain a phase separation between the nanodomains, the size of which is <10 nm, with a controlled morphology and a period of <20 nm, an orientation of the domains perpendicular to the surface to be etched, and a reduction in the number of defects. The temperature T of this heat treatment is preferably such that it is less than 290° C., preferably less than 180° C., and greater than the highest glass transition temperature of the blocks constituting the copolymer. It is carried out under a solvent atmosphere, or thermally, or by a combination of these two methods. This heat treatment, or annealing, enables the block copolymer to become correctly organized, that is to say to especially obtain a phase separation between the nanodomains, a controlled morphology of the nanodomains, a preferential orientation of the nanodomains, and a reduction in the number of defects.

The block copolymer film obtained has an ordered structuring for a given total degree of polymerization.

Depending on whether the macro-initiator is mono- or dihydroxylated, the copolymer obtained is a diblock copolymer of PBL-b-PBT type or triblock copolymer of PBL-b-PBT-b-PBL type.

The block copolymer according to the invention is preferably synthesized at a temperature ranging from 20 to 120° C. and more preferentially between 30 and 60° C., in particular when the solvent is toluene. Indeed, when the macro-initiator is a hydrogenated or non-hydrogenated hydroxytelechelic polybutadiene, it is possible to obtain, at a temperature of approximately 30° C., PBL-b-Krasol®-b-PBL or PBL-b-Krasol® H-b-PBL block copolymers having number-average molecular weights Mₙ ranging up to 20 000 g/mol in a few hours and with a yield of greater than or equal to 85% after purification.

The molar ratio of initiator/catalyst (HOTf) is preferably between 1/1 and 1/2.

Finally, the reagents used in this process are preferably dried before being used, especially by vacuum treatment, distillation or drying using an inert desiccant.

The cylindrical or lamellar morphology of the nanodomains formed in this way depends on the molar ratio of monomer (BBL) to macro-initiator in the starting mixture, but also on the nature of the macro-initiator forming the second block of the block copolymer and on its degree of polymerization.

The molar ratio of BBL monomer to macro-initiator is preferably between 60/1 and 160/1.

More particularly, in order to obtain a lamellar morphology, the molar ratio of monomer (β-BL) to macro-initiator is preferably between 0.9 N and 1.1 N, and in order to obtain a cylindrical morphology, the molar ratio of monomer (β-BL) to macro-initiator is preferably between 0.25 N and 0.35 N or between 1.8 N and 2.2 N, N being the degree of polymerization of the oligomer or polymer forming the macro-initiator.

In the specific example of Krasol LBH-P3000® or Krasol HLBH-P3000®, the number-average molar mass of which is approximately 3000 g/mol, in order to obtain a lamellar morphology, the molar ratio of monomer (β-BL) to macro-initiator is between 60/1 and 90/1 and in order to obtain a cylindrical morphology, the molar ratio of monomer (β-BL) to macro-initiator is advantageously between 100/1 and 160/1.

After having synthesized this copolymer film, having deposited it on a surface to be etched and having subjected it to annealing in accordance with the preceding description, the first polybutyrolactone (PBL) block, which is biodegradable, is advantageously removed in order to form a nanolithography resist comprising a porous pattern perpendicular to the surface to be etched and having a period L₀≤20 nm.

A block copolymer according to the invention therefore makes it possible to obtain an assembly of blocks perpendicular to the surface on which it is deposited, with a considerable phase segregation, making it possible to obtain nanodomains of small sizes, of approximately 1 nanometre to a few nanometres, and of controlled morphology and a period of less than or equal to 20 nm. Such a block copolymer therefore allows better control of the lithography process, the resolution of which is high and compatible with the current requirements in terms of component dimensions.

The following examples nonlimitingly illustrate the scope of the invention:

The following general procedure was used to carry out the processes described below.

The toluene is dried using an MBraun SPS-800 solvent purification system. The methanesulphonic acid (MSA) and the trifluoromethanesulphonic acid (HTOf) were used without additional purification. The diisopropylethylamine (DIEA) was dried and distilled over CaH₂ and stored over potassium hydroxide (KOH).

The Schlenk tubes were dried with a heat gun under vacuum in order to remove any trace of moisture.

The reaction was monitored by ¹H NMR (proton nuclear magnetic resonance) on a Brucker Avance 300 and 500 device and by size exclusion chromatography (SEC) in THF. For this purpose, samples were withdrawn, neutralized with DIEA, evaporated and taken up in an appropriate solvent with a view to their characterization. ¹H NMR makes it possible to quantify the degrees of polymerization (DPs) of the β-BL and ε-CL monomers by determining the integration ratio of half of the signals of the —CH₂— groups bearing the OC(═O) functional group and the C═O functional group, respectively, to the signals of the CH₂ protons bearing the —OH functional group initially on the initiator. The spectra are recorded in deuterated chloroform on a 300 MHz spectrometer. The number-average molecular weight Mn and the degree of polydispersity (Ð) of the samples of copolymers withdrawn are measured by size exclusion chromatography SEC in THF with polystyrene calibration.

The measurement by differential scanning calorimetry, denoted DSC, makes it possible to study the glass transitions and the crystallization. DSC is a thermal analysis technique which makes it possible to measure the differences in the exchanges of heat between a sample to be analysed and a reference during phase transitions. A Netzsch DSC204 differential scanning calorimeter was used to carry out this study.

The calorimetry analyses were carried out between −80 and 130° C. and the temperature values were recorded during the second rise in temperature (at a rate of 10° C./min).

Analysis by small angle X-ray scattering, denoted SAXS, makes it possible to study the structural properties of the block copolymers synthesized on a scale smaller than 100 nm. This analytical technique consists in causing monochromatic radiation to scatter through the sample to be analysed. The scattered intensity is collected as a function of the scattering angle passing through the sample, the scattering angle being very close to the direct beam. The scattered photons provide information relating to the fluctuation of the electron densities in the heterogeneous material. In order to carry out SAXS analyses, a Nanostar SAXS (Bruker) apparatus or the BM-26B station of the DUBBLE line at the European synchrotron Radiation Facility (ESFR) was used.

In the following examples, diblock and triblock copolymers, based on polycaprolactone (PCL) on the one hand and based on polybutyrolactone (PBL) on the other were prepared and compared. In the case of PBL, trifluoromethanesulphonic acid (HOTf) was used as catalyst, while for PCL, methanesulphonic acid (MSA), which is weaker, is sufficiently active.

In all the cases the polymerization of PBL or PCL is total and takes place with a very good level of control, that is to say with effective incorporation of the polyester block onto the hydroxylated end(s) of the polybutadienes (Krasol) or the hydroxylated polydimethylsiloxane (PDMS) and with a very low impact on the transfer reactions. The block structure of the copolymer is confirmed by NMR and SEC analyses of the polymers.

The monomer/macro-initiator ratio in the initial mixture for the synthesis of each block copolymer differs from one example to another, so as to vary the volume fractions between the blocks of different nature. The ability of these copolymers to segregate and to become nanostructured was firstly studied by DSC then by SAXS and/or microscopy analysis was also carried out. The results of the analyses are collated in table I below.

### Example 1 (Comparative): Preparation of a Poly(ε-Caprolactone)₄₃-Block-Krasol® LBH-P3000-Block-Poly(ε-Caprolactone)₄₃ Triblock Copolymer

The macro-initiator (Krasol® LBH-P3000, 2 eq., 1.5 g) and also the ε-CL (80 eq., 4.11 g) are weighed in a glovebox and introduced into a dry Schlenk flask. The Schlenk flask is placed under a controlled argon atmosphere, then the solvent (9 ml of toluene, [ε-CL]₀=4 mol/l) and methanesulphonic acid (1 eq., 78 μl) are added successively. The reaction medium is stirred under argon at 30° C. for 2 h 30. Once the monomer has been entirely consumed, established from ¹H NMR monitoring, an excess of diisopropylethylamine (DIEA) is added to neutralize the acid catalyst. The solvent is then evaporated under vacuum. The polymer obtained is then dissolved in the minimum amount of dichloromethane, then precipitated by addition to cold methanol, filtered and dried under vacuum.

The polymerization reaction of the ε-CL monomer with the macro-initiator is as follows:

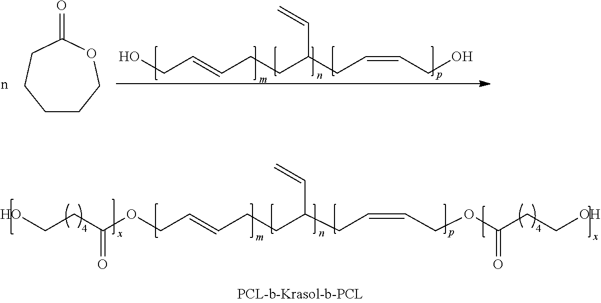

### The Results Obtained are as Follows:

A PCL₄₃-b-Krasol®-b-PCL₄₃ triblock copolymer is obtained with a degree of conversion of 99% and a yield of greater than 90%.

SEC: Mₙ=18 000 g/mol; Ð=1.18

DSC: Tg1=−55.4° C.; Tm: 52.7° C.; overall degree of crystallinity=45%

¹H NMR (CDCl₃, 300 MHz): 5.55-5.33 (m, 40×1H, CHCH═CH₂+2×2×10H, —CH—CH═CH—CH—), 4.95 (m, 1×40×2H, CH—CH═CH₂), 4.06 (t, 2×43×2H, OCH₂CH₂), 3.64 (t, 2×2H, terminal CH₂OH), 2.35 (m, 2×43×2H, COCH₂), 2.02 (m, 40×1H, CHCH═CH₂+2×2×10×2H, —CH₂—CH═CH—CH₂—), 1.65 (m, 2×2×43×2H, COCH₂CH₂CH₂CH₂CH₂O), 1.38-1.25 (m, 2×43×2H, COCH₂CH₂CH₂CH₂CH₂O, 40×2H, CH₂—CH₂—CH).

### Example 2 (Comparative): Preparation of a Poly(ε-Caprolactone)₈₀-Block-Krasol LBH-P3000-Block-Poly(ε-Caprolactone)₈₀ Triblock Copolymer

The macro-initiator (Krasol LBH-P3000, 2 eq., 1.5 g) and also the ε-CL (160 eq., 8.22 g) are weighed in a glovebox and introduced into a dry Schlenk flask. The Schlenk flask is placed under a controlled argon atmosphere, then the solvent (18 ml of toluene, [ε-CL]o=4 mol/l) and methanesulphonic acid (1 eq., 156 μl) are added successively. The reaction medium is stirred under argon at 30° C. for 2 h 30. Once the monomer has been entirely consumed, established from ¹H NMR monitoring, an excess of diisopropylethylamine (DIEA) is added to neutralize the acid catalyst. The solvent is then evaporated under vacuum. The polymer obtained is then dissolved in the minimum amount of dichloromethane, then precipitated by addition to cold methanol, filtered and dried under vacuum.

### The Results Obtained are as Follows:

A PCL₈₀-b-Krasol-b-PCL₈₀ triblock copolymer is obtained with a degree of conversion of 99% and a yield of greater than 90%.

SEC: Mₙ=33 000 g/mol; Ð=1.13

DSC: Tg₁=−55.6° C.; Tm: 52.7° C.; overall degree of crystallinity=42%

¹H NMR (CDCl₃, 300 MHz): 5.55-5.33 (m, 40×1H, CHCH═CH₂+2×2×10H, —CH—CH═CH—CH—), 4.95 (m, 1×40×2H, CH—CH═CH₂), 4.06 (t, 2×80×2H, OCH₂CH₂), 3.64 (t, 2×2H, terminal CH₂OH), 2.35 (m, 2×80×2H, COCH₂), 2.02 (m, 40×1H, CHCH═CH₂+2×2×10×2H, —CH₂—CH═CH—CH₂—), 1.65 (m, 2×2×80×2H, COCH₂CH₂CH₂CH₂CH₂O), 1.38-1.25 (m, 2×80×2H, COCH₂CH₂CH₂CH₂CH₂O, 40×2H, CH₂—CH₂—CH).

### Example 3: Preparation of a Poly(β-Butyrolactone)₇₅-Block-Krasol LBH-P3000-Block-Poly(β-Butyrolactone)₇₅ Triblock Copolymer

The macro-initiator (Krasol LBH-P3000, 2 eq., 1.27 g) and also the β-BL (160 eq., 5.25 g) are weighed in a glovebox and introduced into a dry Schlenk flask. The Schlenk flask is placed under a controlled argon atmosphere, then the solvent (4.6 ml of toluene, [β-BL]₀=7 mol/l) and trifluoromethanesulphonic acid (2 eq., 91 μl) are added successively. The reaction medium is stirred under argon at 30° C. for 3 h 30. Once the β-BL monomer has been entirely consumed, established from ¹H NMR monitoring, an excess of diisopropylethylamine (DIEA) is added to neutralize the acid catalyst. The solvent is then evaporated under vacuum. The polymer obtained is then dissolved in the minimum amount of dichloromethane, then precipitated by addition to cold methanol, filtered and dried under vacuum.

The polymerization reaction of the β-BL monomer with the macro-initiator is as follows:

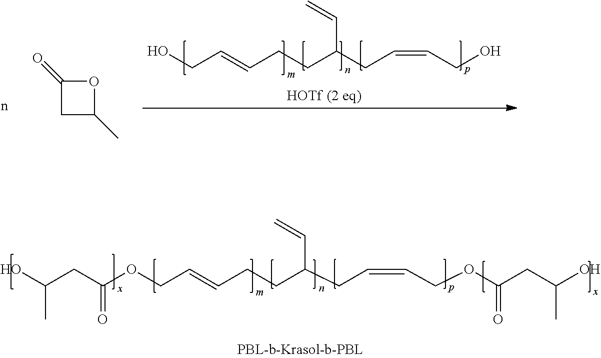

### The Results Obtained are as Follows:

A PBL₇₅-b-Krasol-b-PBL₇₅ triblock copolymer is obtained with a degree of conversion of greater than 94% and a yield of greater than 90%.

SEC (THF): Mₙ=18 000 g/mol; Ð (=M_{w}/Mₙ)=1.15

DSC: T_{g1}=−40.5° C. and T_{g2}=−10.8° C.

¹H NMR (CDCl₃, 300 MHz): 5.52-5.33 (m, 40×1H, CHCH═CH₂+2×2×10H, —CH—CH═CH—CH—+2×75×1H, xOCH), 4.96 (m, 1×40×2H, CH—CH═CH₂), 4.19 (m, 2×1×1H, HOCH), 4.06 (m, 2×2H, initiation CH₂O), 2.59 (m, 2×75×1H, COCH₂), 2.48 (m, 2×75×1H, COCH₂) 2.02 (m, 40×1H, CHCH═CH₂+2×2×10×2H, —CH₂—CH═CH—CH₂—), 1.58 (m, 2×75×3H, CH₃), 1.25 (m, 40×2H, CH₂—CH₂—CH).

### Example 4: Preparation of a Poly(β-Butyrolactone)₃₇-Block-Krasol LBH-P3000-Block-Poly(β-Butyrolactone)₃₇ Triblock Copolymer

The macro-initiator (Krasol LBH-P3000, 2 eq., 2.35 g) and also the β-BL (80 eq., 4.60 g) are weighed in a glovebox and introduced into a dry Schlenk flask. The Schlenk flask is placed under a controlled argon atmosphere, then the solvent (14 ml of toluene, [β-BL]₀=4 mol/l) and trifluoromethanesulphonic acid (2 eq., 168 μl) are added successively. The reaction medium is stirred under argon at 30° C. for 2 h 30. Once the monomer has been entirely consumed, established from ¹H NMR monitoring, an excess of diisopropylethylamine (DIEA) is added to neutralize the acid catalyst. The solvent is then evaporated under vacuum. The polymer obtained is then dissolved in the minimum amount of dichloromethane, then precipitated by addition to cold methanol, filtered and dried under vacuum.

### The Results Obtained are as Follows:

A PBL₃₇-b-Krasol-b-PBL₃₇ triblock copolymer is obtained with a degree of conversion of 99% and a yield of greater than 90%.

SEC: Mₙ=12 000 g/mol; Ð=1.19

DSC: T_{g1}=−39.9° C. and T_{g2}=−17.4° C.

¹H NMR (CDCl₃, 300 MHz): 5.52-5.33 (m, 40×1H, CHCH═CH₂+2×2×10H, —CH—CH═CH—CH—+2×37×1H, xOCH), 4.96 (m, 1×40×2H, CH—CH═CH₂), 4.19 (m, 2×1×1H, HOCH), 4.06 (m, 2×2H, initiation CH₂OH), 2.49 (m, 2×37×1H, COCH₂), 2.35 (m, 2×37×1H, COCH₂), 2.02 (m, 40×1H, CHCH═CH₂+2×2×10×2H, —CH₂—CH═CH—CH₂—), 1.60 (m, 2×37×3H, CH₃), 1.25 (m, 40×2H, CH₂—CH₂—CH).

### Example 5: Preparation of a Poly(β-Butyrolactone)₃₉-Block-Krasol H LBH-P3000-Block-Poly(β-Butyrolactone)₃₉ Triblock Copolymer

The macro-initiator (Krasol HLBH-P3000, 2 eq., 0.77 g) and also the β-BL (80 eq., 1.28 g) are taken off in a glovebox and introduced into a dry Schlenk flask. The Schlenk flask is placed under a controlled argon atmosphere, then the solvent (3.7 ml of toluene, [β-BL]o=4 mol/l) and trifluoromethanesulphonic acid (2 eq., 45 μl) are added successively. The reaction medium is stirred under argon at 30° C. for 1 h 15. Once the monomer has been entirely consumed, established from ¹H NMR monitoring, an excess of diisopropylethylamine (DIEA) is added to neutralize the acid catalyst. The solvent is then evaporated under vacuum. The polymer obtained is then dissolved in the minimum amount of dichloromethane, then precipitated by addition to cold methanol, filtered and dried under vacuum.

The polymerization reaction of the ε-CL monomer with the macro-initiator (hydrogenated hydroxytelechelic polybutadiene) is as follows:

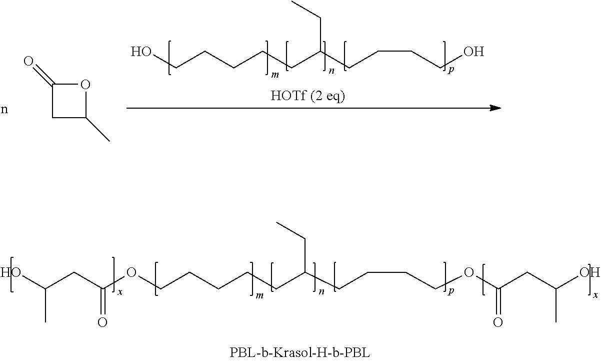

### The Results Obtained are as Follows:

A PBL₃₉-b-Krasol H-b-PBL₃₉ triblock copolymer is obtained with a degree of conversion of 99% and a yield of greater than 90%.

SEC: Mₙ=14 500 g/mol; Ð=1.14

DSC: T_{g1}=−49.5° C. and T_{g2}=−7.1° C.

¹H NMR (CDCl₃, 300 MHz): 5.24 (m, 2×39×1H, xOCH), 4.19 (m, 2×1×1H, HOCH), 4.08 (m, 2×2H, initiation CH₂O), 2.58 (m, 2×39×1H, COCH₂), 2.47 (m, 2×39×1H, COCH₂), 1.25 (m, 36×1H, CH₂—CH—CH₂+2×36×2H, CH—CH₂—CH₃+2×4×10×2H, —CH₂—CH₂—CH₂—+2×39×3H, CH₃), 0.82 (m, 36×3H, CH₂—CH₃).

### Example 6: Preparation of a Poly(β-Butyrolactone)₅₄-Block-Krasol H LBH-P3000-Block-Poly(β-Butyrolactone)₅₄ Triblock Copolymer

The macro-initiator (Krasol HLBH-P3000, 2 eq., 0.5 g) and also the β-BL (120 eq., 1.71 g) are taken off in a glovebox and introduced into a dry Schlenk flask. The Schlenk flask is placed under a controlled argon atmosphere, then the solvent (4.8 ml of toluene, [β-BL]o=4 mol/1) and trifluoromethanesulphonic acid (2 eq., 29 μl) are added successively. The reaction medium is stirred under argon at 30° C. for 3 h 30. Once the monomer has been entirely consumed, established from ¹H NMR monitoring, an excess of diisopropylethylamine (DIEA) is then added to neutralize the catalyst. The solvent is then evaporated under vacuum. The polymer obtained is then dissolved in the minimum amount of dichloromethane, then precipitated by addition to cold methanol, filtered and dried under vacuum.

### The Results Obtained are as Follows:

A PBL₅₄-b-Krasol H-b-PBL₅₄ triblock copolymer is obtained with a degree of conversion of 99% and a yield of greater than 90%.

SEC: Mₙ=15 800 g/mol; Ð=1.20

DSC: T_{g1}=−52.4° C. and T_{g2}=−4.3° C.

¹H NMR (CDCl₃, 300 MHz): 5.25 (m, 2×54×1H, xOCH), 4.19 (m, 2×1×1H, HOCH), 4.08 (m, 2×2H, initiation CH₂O), 2.58 (m, 2×54×1H, COCH₂), 2.47 (m, 2×54×1H, COCH₂), 1.25 (m, 36×1H, CH₂—CH—CH₂+2×36×2H, CH—CH₂—CH₃+2×4×10×2H, —CH₂—CH₂—CH₂—+2×54×3H, CH₃), 0.83 (m, 36×3H, CH₂—CH₃).

### Example 7: Preparation of a PDMS-b-PBL Diblock Copolymer

The macro-initiator, hydroxylated PDMS (PDMS, Mn=4670 g/mol, 1 eq., 2 g) and also the β-BL (60 eq., 2.21 g) are taken off in a glovebox and introduced into a dry Schlenk flask. The Schlenk flask is placed under a controlled argon atmosphere, then the solvent (6.4 ml of toluene, [β-BL]₀=4 mol/1) and trifluoromethanesulphonic acid (1 eq., 37 μl) are added successively. The reaction medium is stirred under argon at 30° C. for 6 h 30. Once the monomer has been entirely consumed, established from ¹H NMR monitoring, an excess of diisopropylethylamine (DIEA) is then added to neutralize the catalyst. The solvent is then evaporated under vacuum. The polymer obtained is then dissolved in the minimum amount of dichloromethane, then precipitated by addition to cold methanol, filtered and dried under vacuum.

¹H NMR (CDCl₃, 300 MHz): 5.25 (m, 2×55×1H, xOCH), 4.19 (m, 2×1×1H, HOCH), 4.08 (m, 2×2H, initiation CH₂O), 2.58 (m, 2×55×1H, COCH₂), 2.47 (m, 2×55×1H, COCH₂), 0.10 (s, 74×6H, Si(CH₃)₂).

Thermal analyses by differential scanning calorimetry (DSC) of the PBL-b-Krasol-b-PBL, or PBL-b-Krasol H-b-PBL block copolymers show two very distinct glass transition temperatures, T_{g1} and T_{g2}. Each of these temperatures is close to the glass transition temperature of each corresponding homopolymer (for PBL, Tg≈−10° C., for Krasol, Tg=−55° C.), indicating the observation of a phase segregation between the blocks in the solid state. On the other hand, these thermal analyses for the PCL-b-Krasol-b-PCL copolymers show a single T_{g} value. Given the proximity of the T_{g} values of the corresponding homopolymers (for PCL, Tg=−60° C. and for Krasol, Tg=−55° C.) it is difficult to draw conclusions as to the ability of these blocks to segregate solely based on DSC analysis.

SAXS analyses, carried out on a Nanostar SAXS apparatus (Bruker) or at the BM-26B station of the DUBBLE line at the European synchrotron Radiation Facility (ESFR), shed more light on the differing behaviour of the block copolymers depending on whether they incorporate PBL or PCL blocks. For the block copolymers based on PCL, there is no nanostructuring with a well-defined morphology, but rather simply a separation of the phases due to the crystallinity of the PCL, and the amorphous PCL/Krasol phases are miscible. On the other hand, in the case of PBL, nanostructuring with a well-defined morphology is observed, whether this is with Krasol, hydrogenated Krasol or PDMS. The nanostructuring morphology depends on the volume fractions of PBL in the block copolymer, which are directly linked to the molar ratio of BBL monomer to the macro-initiator polymer or oligomer. In all cases, very small values of period L₀ were measured: between 10.5 and 13.7 nm. The different morphologies observed as a function of the molar fractions of PBL and of Krasol® or PDMS, and the period L₀ measured, are indicated in table I below, in which all the results obtained over the different samples synthesized in accordance with examples 1 to 7 are collated.

TABLE I

| | | Mₙ | | | Mₙ | | T_{g} | Period | Morphology |
|---|---|---|---|---|---|---|---|---|---|
| | | Polyester | | | Copo | | Copo | L₀ | (L: lamellar C: |
| Example | Composition* | (g/mol) | f_{molar·Krasol} | f_{molar·polyester} | (g/mol) | Ð^{#} | (° C.) | (nm) | cylindrical) |
| 1 | PCL₄₃-b- | 12 300 | 0.26 | 0.74 | 18 000 | 1.18 | −55.4 | | No |
| | Krasol-b- | | | | | | | | nanostructuring |
| | PCL₄₃ | | | | | | | | |
| 2 | PCL₈₀-b- | 20 800 | 0.16 | 0.84 | 33 000 | 1.13 | −55.6 | | No |
| | Krasol-b- | | | | | | | | nanostructuring |
| | PCL₈₀ | | | | | | | | |
| 3 | PBL₇₅-b- | 15 400 | 0.16 | 0.84 | 18 000 | 1.15 | −40.5; −10.8 | 12.5 | C |
| | Krasol-b- | | | | | | | | |
| | PBL₇₅^{a} | | | | | | | | |
| 4 | PBL₃₇-b- | 8 900 | 0.28 | 0.72 | 12 000 | 1.19 | −39.9; −17.4 | 10.5 | L |
| | Krasol-b- | | | | | | | | |
| | PBL₃₇^{a} | | | | | | | | |
| 5 | PBL₃₉-b- | 9 100 | 0.34 | 0.66 | 14 500 | 1.14 | −49.5; −7.1 | 13.7 | L |
| | Krasol H-b- | | | | | | | | |
| | PBL₃₉^{a} | | | | | | | | |
| 6 | PBL₅₄-b- | 12 400 | 0.25 | 0.75 | 15 800 | 1.20 | −52.4; −4.3 | 13.7 | C |
| | Krasol H-b- | | | | | | | | |
| | PBL₅₄^{a} | | | | | | | | |

The PBL-b-Krasol-b-PBL or PBL-b-Krasol H-b-PBL triblock copolymers giving rise to nanostructuring were then chosen for microscopy analysis. For this purpose, a solution of copolymer is deposited in the form of a thin film on a surface, then the solvent is evaporated and the film is annealed at a temperature of 120° C. for 24 hours. The films deposited are approximately 30 nm thick. The results of microscopy analysis confirm nanostructuring with cylindrical or lamellar nanodomains perpendicular to the surface and having a mean period L₀ of 13 nm.

The block copolymers incorporating a polybutyrolactone polyester block are thus capable of segregating, giving rise to structuring on the nanometre scale, whereas no nanostructuring is observed for the triblock copolymers of equivalent size based on polycaprolactone.

Moreover, the copolymers obtained based on polybutyrolactone are capable of segregating for low molecular weights, typically of less than 20 000 g/mol, enabling various morphologies to be achieved depending on their composition, with very small structuring periods of less than 20 nm.

This behaviour proves particularly advantageous in the context of applications in DSA (directed self-assembly) nanolithography, in which it is sought to obtain nanostructuring in periodic structures with very small copolymer periods, in order to obtain nanolithography resists with very high resolutions.

The copolymer according to the invention differs very greatly from conventional PS-b-PMMA block copolymers which do not make it possible to obtain periods smaller than 20 nm.

1. A block copolymer film nanostructured in nanodomains, said copolymer comprising at least one first biodegradable block of polyester type and a second block of a different chemical nature than the first block, wherein
the first block of polyester type is polybutyrolactone (PBL) and
the second block is derived from an oligomer or from a polymer bearing a hydroxyl function on at least one end and acting as macro-initiator of the polymerization of β-butyrolactone (β-BL) to give polybutyrolactone (PBL).

2. The block copolymer film according to claim 1, wherein the block copolymer is a diblock or triblock copolymer.

3. The copolymer film according to claim 1, wherein the number-average molecular weight of each PBL block is between 1000 and 20 000 g/mol.

4. The block copolymer film according to claim 1, wherein the number-average molecular weight of the block copolymer is between 2000 and 30 000 g/mol.

5. The block copolymer film according to claim 1, wherein the molar ratio of monomer (β-BL) to macro-initiator is between 60/1 and 160/1.

6. The block copolymer film according to claim 1, wherein the second block forming the macro-initiator is derived from an oligomer or from a mono- or polyhydroxylated polymer chosen from:
(alkoxy)polyalkylene glycols;
poly(alkyl)alkylene adipate diols; or
polysiloxanes, or
optionally hydrogenated mono- or dihydroxylated polydienes; or
mono- or polyhydroxylated polyalkylenes; modified or unmodified; or
a vinyl co-oligomer or copolymer from the family of acrylic, methacrylic, styrene or diene polymers, which results from copolymerization between acrylic, methacrylic, styrene or diene monomers and functional monomers having a hydroxyl group, or
a vinyl copolymer obtained by controlled radical polymerization, in which the radical initiator and/or the control agent bear at least one hydroxyl or thiol function.

7. A method of producing a nanolithography resist, comprising removing the first block from the block copolymer film according to claim 1.

8. A method of coating a surface, comprising depositing on the surface the block copolymer film according to claim 1.
